(19) United States
(12) Patent Application Publication
(10) Pub. No.: US 2017/0076917 A1
(43) Pub. Date: Mar. 16, 2017

(54) Plasma Module With Slotted Ground Plate

(71) Applicant: Applied Materials, Inc., Santa Clara, CA (US)

(72) Inventors: Joseph Yudovsky, Campbell, CA (US); John C. Forster, Mt. View, CA (US); Kallol Bera, Fremont, CA (US); Somesh Khandelwal, Sunnyvale, CA (US); Mandyam Sriram, San Jose, CA (US); Keiichi Tanaka, San Jose, CA (US); Kenji Takeshita, Sunnyvale, CA (US); Nobuhiro Sakamoto, Tokyo (JP); Takumi Yanagawa, Fremont, CA (US)

(21) Appl. No.: 15/260,876

(22) Filed: Sep. 9, 2016

Related U.S. Application Data
(60) Provisional application No. 62/217,705, filed on Sep. 11, 2015.

(51) Int. Cl. H01J 37/32; C23C 16/458; C23C 16/455

(52) U.S. Cl. CPC H01J 37/32623; C23C 16/45544; C23C 16/45536; C23C 16/4584; H01J 37/32082; H01J 37/3244; H01J 37/32752

(57) ABSTRACT

A plasma source assembly for use with a processing chamber includes a blocker plate with at least one elongate slot through the blocker plate. The elongate slots can be have different lengths and angles relative to sides of the blocker plate.

### CROSS-REFERENCE TO RELATED APPLICATIONS

This application claims priority to U.S. Provisional Application No. 62/217,705, filed Sep. 11, 2015, the entire disclosure of which is hereby incorporated by reference herein.

### FIELD

Embodiments of the disclosure generally relate to an apparatus for processing substrates. More particularly, embodiments of the disclosure relate to modular capacitively coupled plasma sources for use with processing chambers like batch processors.

### BACKGROUND

Semiconductor device formation is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

Some ALD systems, especially spatial ALD systems with rotating substrate platens, benefit from a modular plasma source, i.e., a source that can be easily inserted into the system. The plasma source consists of a volume where plasma is generated, and a way to expose a workpiece to a flux of charged particles and active chemical radical species.

Capacitively coupled plasma (CCP) sources are commonly used in these applications as it is easy to generate plasma in a CCP in the pressure range (1-50 Torr) commonly used in ALD applications. An array of holes is often used to expose the wafer to the active species of the plasma. However, it has been found that the relative density of active species is not uniform across the entire array of holes.

Therefore, there is a need in the art for capacitively coupled plasma sources which provide increased active species density uniformity.

### SUMMARY

One or more embodiments of the disclosure are directed to plasma source assemblies comprising a housing, a blocker plate and an RF hot electrode. The blocker plate is in electrical communication with the housing. The blocker plate has an inner peripheral edge, an outer peripheral edge, a first side and a second side defining a field. An elongate slot is within the field and extends through the blocker plate. The elongate slot has a length and a width. The RF hot electrode is within the housing and has a front face and a back face, an inner peripheral end and an outer peripheral end. The front face of the RF hot electrode is spaced from the blocker plate to define a gap.

Additional embodiments of the disclosure are directed to plasma source assemblies comprising a wedge-shaped housing having an inner peripheral end, an outer peripheral, a first side and a second side. A wedge-shaped blocker plate is in electrical communication with the housing. The blocker plate has an inner peripheral edge, an outer peripheral edge, a first side and a second side defining a field. The field comprises a first elongate slot substantially parallel to the first side of the blocker plate, a second elongate slot extending through the blocker plate substantially parallel to the second side of the blocker plate and a third elongate slot between the first elongate slot and the second elongate slot. The third elongate slot has a length in the range of about 20% to about 80% of the length of the second elongate slot. The second elongate slot has a length in the range of about 20% to about 80% of the length of the first elongate slot. A wedge-shaped RF hot electrode is within the housing and has a front face and a back face, an inner peripheral end and an outer peripheral end, the front face of the RF hot electrode spaced from the blocker plate to define a gap.

Further embodiments of the disclosure are directed to processing chambers. A susceptor assembly is within the processing chamber. The susceptor assembly has a top surface to support and rotate a plurality of substrates around a central axis. A gas distribution assembly is in the processing chamber and has a front surface facing the top surface of the susceptor assembly to direct a flow of gases toward the top surface of the susceptor assembly. The gas distribution assembly includes a plasma source assembly comprising a wedge-shaped housing having an inner peripheral end, an outer peripheral, a first side and a second side. A wedge-shaped blocker plate is in electrical communication with the housing. The blocker plate has an inner peripheral edge, an outer peripheral edge, a first side and a second side defining a field. The field comprises a first elongate slot substantially parallel to the first side of the blocker plate, a second elongate slot extending through the blocker plate substantially parallel to the second side of the blocker plate and a third elongate slot between the first elongate slot and the second elongate slot. The third elongate slot has a length in the range of about 20% to about 80% of a length of the second elongate slot and the second elongate slot has a length in the range of about 20% to about 80% of a length of the first elongate slot. A wedge-shaped RF hot electrode is within the housing. The RF hot electrode has a front face and a back face, an inner peripheral end and an outer peripheral end. The front face of the RF hot electrode is spaced from the blocker plate to define a gap. The inner peripheral end of the blocker plate is spaced further from the top surface of the susceptor assembly than the outer peripheral end of the blocker plate.

### BRIEF DESCRIPTION OF THE DRAWINGS

So that the manner in which the above recited features of embodiments of the disclosure can be understood in detail, a more particular description of embodiments of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic cross-sectional view of a substrate processing system in accordance with one or more embodiments of the disclosure;

FIG. 2 shows a perspective view of a substrate processing system in accordance with one or more embodiment of the disclosure;

FIG. 3 shows a schematic of a substrate processing system in accordance with one or more embodiment of the disclosure;

FIG. 4 shows a schematic view of a front of a gas distribution assembly in accordance with one or more embodiment of the disclosure;

FIG. 5 shows a schematic view of a processing chamber in accordance with one or more embodiment of the disclosure;

FIG. 6 shows a schematic cross-sectional view of a plasma source assembly in accordance with one or more embodiment of the disclosure;

FIG. 7 shows a perspective view of a blocker plate in accordance with one or more embodiments of the disclosure;

FIG. 8 shows a schematic front view of a blocker plate in accordance with one or more embodiments of the disclosure;

FIG. 9 shows a schematic front view of a blocker plate in accordance with one or more embodiments of the disclosure;

FIG. 10 shows a schematic front view of a blocker plate in accordance with one or more embodiments of the disclosure;

FIG. 11 shows a schematic front view of a blocker plate in accordance with one or more embodiments of the disclosure;

FIG. 12 shows a schematic front view of a blocker plate in accordance with one or more embodiments of the disclosure;

FIG. 13 shows a schematic cross sectional view of a plasma source assembly with a tilted blocker plate in accordance with one or more embodiment of the disclosure;

FIG. 14 shows a schematic cross-sectional view of a blocker plate in accordance with one or more embodiments of the disclosure;

FIG. 15 shows a graph of the ion flux of a plasma as a function of the slot width; and

FIG. 16 shows a graph of the ion flux of a plasma as a function of the slot width.

### DETAILED DESCRIPTION

Embodiments of the disclosure provide a substrate processing system for continuous substrate deposition to maximize throughput and improve processing efficiency. The substrate processing system can also be used for pre-deposition and post-deposition plasma treatments.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

As used in this specification and the appended claims, the term “reduced pressure” means a pressure less than about 100 Torr, or less than about 75 Torr, or less than about 50 Torr, or less than about 25 Torr. For example, “medium pressure” defined as in the range of about 1 Torr to about 25 Torr is reduced pressure.

Rotating platen chambers are being considered for many applications. In such a chamber, one or more wafers are placed on a rotating holder (“platen”). As the platen rotates, the wafers move between various processing areas. For example, in ALD, the processing areas would expose the wafer to precursors and reactants. In addition, plasma exposure may be used as a reactant or to treat the film or the substrate surface for enhanced film growth or to modify film properties. Some embodiments of the disclosure provide for uniform deposition and post-treatment (e.g., densification) of ALD films when using a rotating platen ALD chamber.

Rotating platen ALD chambers can deposit films by traditional time-domain processes where the entire wafer is exposed to a first gas, purged and then exposed to the second gas, or by spatial ALD where portions of the wafer are exposed to the first gas and portions are exposed to the second gas and the movement of the wafer through these gas streams deposits the layer.

As used in this specification and the appended claims, the terms “pie-shaped” and “wedge-shaped” are used interchangeably to describe a body that is a generally circular sector. For example, a wedge-shaped segment may be a fraction of a circle or disc-shaped structure. The inner edge of the pie-shaped segment can come to a point or can be truncated to a flat edge or rounded. The path of the substrates can be perpendicular to the gas ports. In some embodiments, each of the gas injector assemblies comprises a plurality of elongate gas ports which extend in a direction substantially perpendicular to the path traversed by a substrate, where a front edge of the gas ports is substantially parallel to the platen. As used in this specification and the appended claims, the term “substantially perpendicular” means that the general direction of movement of the substrates is along a plane approximately perpendicular (e.g., about 45° to 90°) to the axis of the gas ports. For a wedge-shaped gas port, the axis of the gas port can be considered to be a line defined as the mid-point of the width of the port extending along the length of the port.

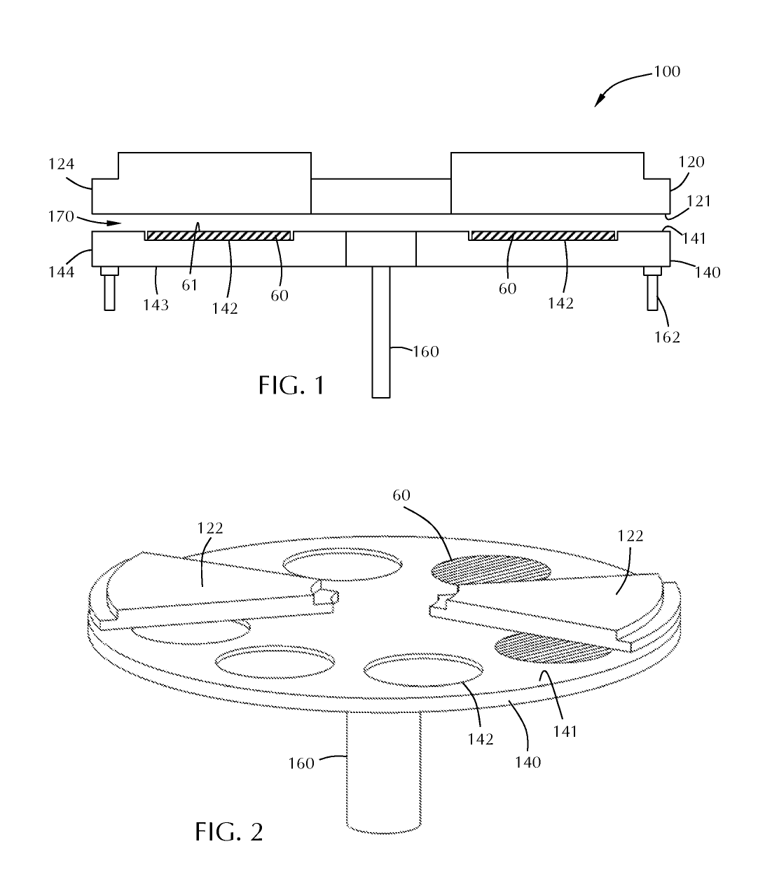

FIG. 1 shows a cross-section of a processing chamber 100 including a gas distribution assembly 120, also referred to as injectors or an injector assembly, and a susceptor assembly 140. The gas distribution assembly 120 is any type of gas delivery device used in a processing chamber. The gas distribution assembly 120 includes a front surface 121 which faces the susceptor assembly 140. The front surface 121 can have any number or variety of openings to deliver a flow of gases toward the susceptor assembly 140. The gas distribution assembly 120 also includes an outer peripheral edge 124 which in the embodiments shown, is substantially round.

The specific type of gas distribution assembly 120 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial ALD gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. The plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the processing region through the purge gas P channel(s). A substrate moving from one end of the gas distribution assembly to the other end will be exposed to each of the process gases in turn, forming a layer on the substrate surface.

In some embodiments, the gas distribution assembly 120 is a rigid stationary body made of a single injector unit. In one or more embodiments, the gas distribution assembly 120 is made up of a plurality of individual sectors (e.g., injector units 122), as shown in FIG. 2. Either a single piece body or a multi-sector body can be used with the various embodiments of the disclosure described.

The susceptor assembly 140 is positioned beneath the gas distribution assembly 120. The susceptor assembly 140 includes a top surface 141 and at least one recess 142 in the top surface 141. The susceptor assembly 140 also has a bottom surface 143 and an edge 144. The recess 142 can be any suitable shape and size depending on the shape and size of the substrates 60 being processed. In the embodiment shown in FIG. 1, the recess 142 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 1, the recess 142 in the top surface 141 of the susceptor assembly 140 is sized so that a substrate 60 supported in the recess 142 has a top surface 61 substantially coplanar with the top surface 141 of the susceptor 140. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 140 of FIG. 1 includes a support post 160 which is capable of lifting, lowering and rotating the susceptor assembly 140. The susceptor assembly may include a heater, or gas lines, or electrical components within the center of the support post 160. The support post 160 may be the primary means of increasing or decreasing the gap between the susceptor assembly 140 and the gas distribution assembly 120, moving the susceptor assembly 140 into proper position. The susceptor assembly 140 may also include fine tuning actuators 162 which can make micro-adjustments to susceptor assembly 140 to create a predetermined gap 170 between the susceptor assembly 140 and the gas distribution assembly 120. In some embodiments, the gap 170 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 100 shown in the Figures is a carousel-type chamber in which the susceptor assembly 140 can hold a plurality of substrates 60. As shown in FIG. 2, the gas distribution assembly 120 may include a plurality of separate injector units 122, each injector unit 122 being capable of depositing a film on the wafer, as the wafer is moved beneath the injector unit. Two pie-shaped injector units 122 are shown positioned on approximately opposite sides of and above the susceptor assembly 140. This number of injector units 122 is shown for illustrative purposes only. It will be understood that more or less injector units 122 can be included. In some embodiments, there are a sufficient number of pie-shaped injector units 122 to form a shape conforming to the shape of the susceptor assembly 140. In some embodiments, each of the individual pie-shaped injector units 122 may be independently moved, removed and/or replaced without affecting any of the other injector units 122. For example, one segment may be raised to permit a robot to access the region between the susceptor assembly 140 and gas distribution assembly 120 to load/unload substrates 60.

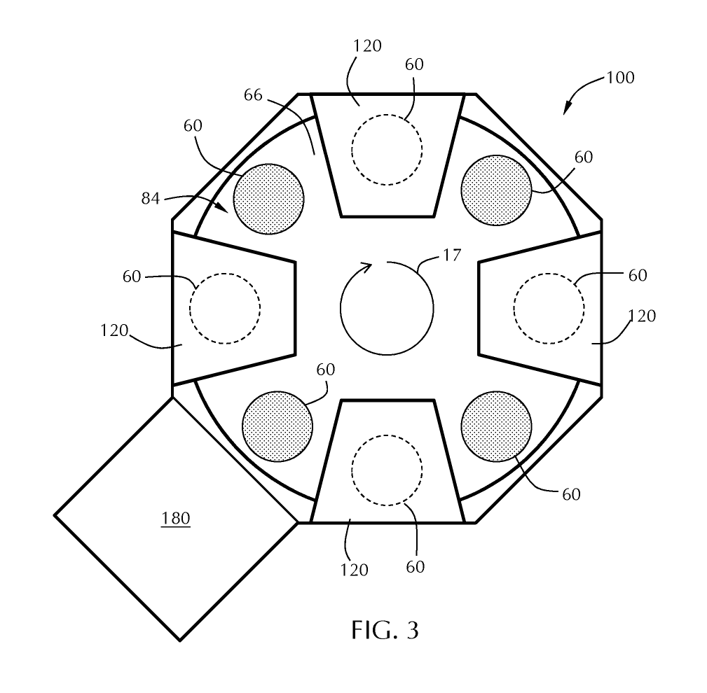

Processing chambers having multiple gas injectors can be used to process multiple wafers simultaneously so that the wafers experience the same process flow. For example, as shown in FIG. 3, the processing chamber 100 has four gas injector assemblies and four substrates 60. At the outset of processing, the substrates 60 can be positioned between the injector assemblies 30. Rotating 17 the susceptor assembly 140 by 45° will result in each substrate 60 which is between gas distribution assemblies 120 to be moved to an gas distribution assembly 120 for film deposition, as illustrated by the dotted circle under the gas distribution assemblies 120. An additional 45° rotation would move the substrates 60 away from the injector assemblies 30. With spatial ALD injectors, a film is deposited on the wafer during movement of the wafer relative to the injector assembly. In some embodiments, the susceptor assembly 140 is rotated in increments that prevent the substrates 60 from stopping beneath the gas distribution assemblies 120. The number of substrates 60 and gas distribution assemblies 120 can be the same or different. In some embodiments, there is the same number of wafers being processed as there are gas distribution assemblies. In one or more embodiments, the number of wafers being processed are fraction of or an integer multiple of the number of gas distribution assemblies. For example, if there are four gas distribution assemblies, there are 4x wafers being processed, where x is an integer value greater than or equal to one.

The processing chamber 100 shown in FIG. 3 is merely representative of one possible configuration and should not be taken as limiting the scope of the disclosure. Here, the processing chamber 100 includes a plurality of gas distribution assemblies 120. In the embodiment shown, there are four gas distribution assemblies (also called injector assemblies 30) evenly spaced about the processing chamber 100. The processing chamber 100 shown is octagonal, however, those skilled in the art will understand that this is one possible shape and should not be taken as limiting the scope of the disclosure. The gas distribution assemblies 120 shown are trapezoidal, but can be a single circular component or made up of a plurality of pie-shaped segments, like that shown in FIG. 2.

The embodiment shown in FIG. 3 includes a load lock chamber 180, or an auxiliary chamber like a buffer station. This chamber 180 is connected to a side of the processing chamber 100 to allow, for example the substrates (also referred to as substrates 60) to be loaded/unloaded from the processing chamber 100. A wafer robot may be positioned in the chamber 180 to move the substrate onto the susceptor.

Rotation of the carousel (e.g., the susceptor assembly 140) can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

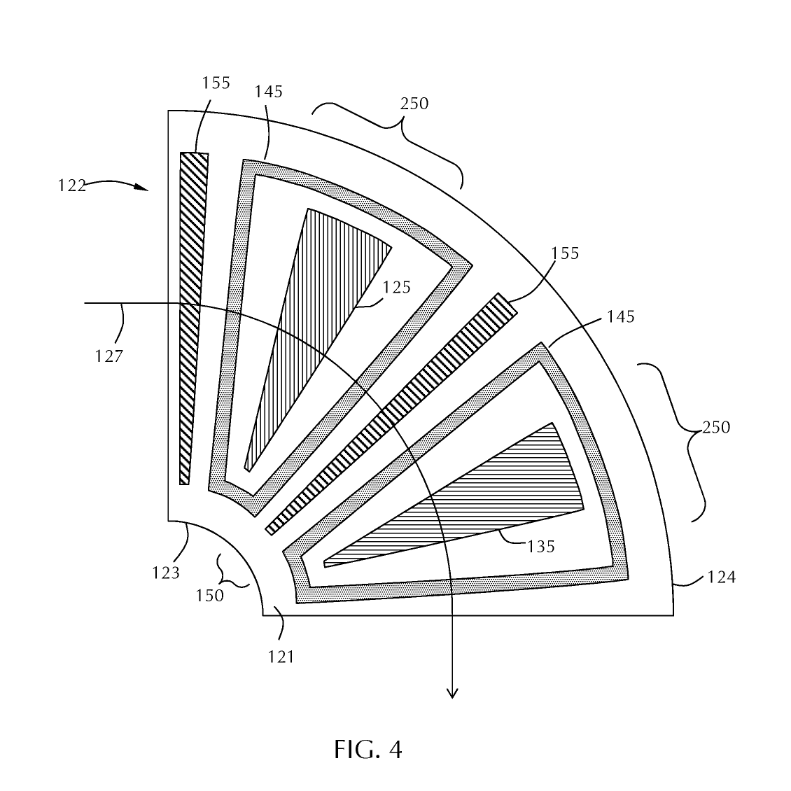

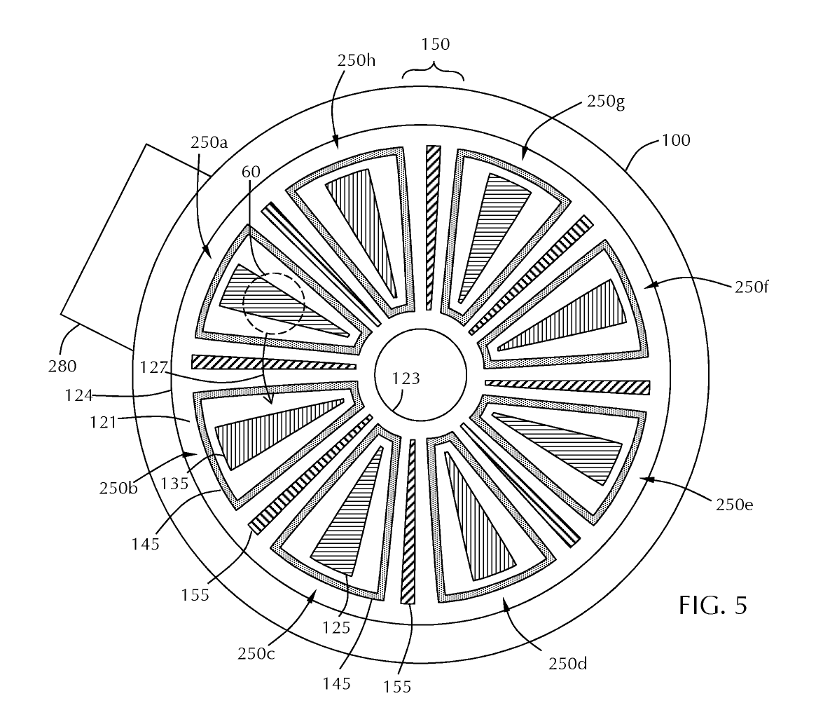

FIG. 4 shows a sector or portion of a gas distribution assembly 220, which may be referred to as an injector unit 122. The injector units 122 can be used individually or in combination with other injector units. For example, as shown in FIG. 5, four of the injector units 122 of FIG. 4 are combined to form a single gas distribution assembly 220. (The lines separating the four injector units are not shown for clarity.) While the injector unit 122 of FIG. 4 has both a first reactive gas port 125 and a second reactive gas port 135 in addition to purge gas ports 155 and vacuum ports 145, an injector unit 122 does not need all of these components.

Referring to both FIGS. 4 and 5, a gas distribution assembly 220 in accordance with one or more embodiment may comprise a plurality of sectors (or injector units 122) with each sector being identical or different. The gas distribution assembly 220 is positioned within the processing chamber and comprises a plurality of elongate gas ports 125, 135, 145 in a front surface 121 of the gas distribution assembly 220. The plurality of elongate gas ports 125, 135, 145, 155 extend from an area adjacent the inner peripheral edge 123 toward an area adjacent the outer peripheral edge 124 of the gas distribution assembly 220. The plurality of gas ports shown include a first reactive gas port 125, a second reactive gas port 135, a vacuum port 145 which surrounds each of the first reactive gas ports and the second reactive gas ports and a purge gas port 155.

With reference to the embodiments shown in FIG. 4 or 5, when stating that the ports extend from at least about an inner peripheral region to at least about an outer peripheral region, however, the ports can extend more than just radially from inner to outer regions. The ports can extend tangentially as vacuum port 145 surrounds reactive gas port 125 and reactive gas port 135. In the embodiment shown in FIGS. 4 and 5, the wedge shaped reactive gas ports 125, 135 are surrounded on all edges, including adjacent the inner peripheral region and outer peripheral region, by a vacuum port 145.

Referring to FIG. 4, as a substrate moves along path 127, each portion of the substrate surface is exposed to the various reactive gases. To follow the path 127, the substrate will be exposed to, or “see”, a purge gas port 155, a vacuum port 145, a first reactive gas port 125, a vacuum port 145, a purge gas port 155, a vacuum port 145, a second reactive gas port 135 and a vacuum port 145. Thus, at the end of the path 127 shown in FIG. 4, the substrate has been exposed to gas streams from the first reactive gas port 125 and the second reactive gas port 135 to form a layer. The injector unit 122 shown makes a quarter circle but could be larger or smaller. The gas distribution assembly 220 shown in FIG. 5 can be considered a combination of four of the injector units 122 of FIG. 4 connected in series.

The injector unit 122 of FIG. 4 shows a gas curtain 150 that separates the reactive gases. The term “gas curtain” is used to describe any combination of gas flows or vacuum that separate reactive gases from mixing. The gas curtain 150 shown in FIG. 4 comprises the portion of the vacuum port 145 next to the first reactive gas port 125, the purge gas port 155 in the middle and a portion of the vacuum port 145 next to the second reactive gas port 135. This combination of gas flow and vacuum can be used to prevent or minimize gas phase reactions of the first reactive gas and the second reactive gas.

Referring to FIG. 5, the combination of gas flows and vacuum from the gas distribution assembly 220 form a separation into a plurality of processing regions 250. The processing regions are roughly defined around the individual reactive gas ports 125, 135 with the gas curtain 150 between 250. The embodiment shown in FIG. 5 makes up eight separate processing regions 250 with eight separate gas curtains 150 between. A processing chamber can have at least two processing region. In some embodiments, there are at least three, four, five, six, seven, eight, nine, 10, 11 or 12 processing regions.

During processing a substrate may be exposed to more than one processing region 250 at any given time. However, the portions that are exposed to the different processing regions will have a gas curtain separating the two. For example, if the leading edge of a substrate enters a processing region including the second reactive gas port 135, a middle portion of the substrate will be under a gas curtain 150 and the trailing edge of the substrate will be in a processing region including the first reactive gas port 125.

A factory interface 280, which can be, for example, a load lock chamber, is shown connected to the processing chamber 100. A substrate 60 is shown superimposed over the gas distribution assembly 220 to provide a frame of reference. The substrate 60 may often sit on a susceptor assembly to be held near the front surface 121 of the gas distribution assembly 120 (also referred to as a gas distribution plate). The substrate 60 is loaded via the factory interface 280 into the processing chamber 100 onto a substrate support or susceptor assembly (see FIG. 3). The substrate 60 can be shown positioned within a processing region because the substrate is located adjacent the first reactive gas port 125 and between two gas curtains 150a, 150b. Rotating the substrate 60 along path 127 will move the substrate counter-clockwise around the processing chamber 100. Thus, the substrate 60 will be exposed to the first processing region 250a through the eighth processing region 250h, including all processing regions between. For each cycle around the processing chamber, using the gas distribution assembly shown, the substrate 60 will be exposed to four ALD cycles of first reactive gas and second reactive gas.

The conventional ALD sequence in a batch processor, like that of FIG. 5, maintains chemical A and B flow respectively from spatially separated injectors with pump/purge section between. The conventional ALD sequence has a starting and ending pattern which might result in non-uniformity of the deposited film. The inventors have surprisingly discovered that a time based ALD process performed in a spatial ALD batch processing chamber provides a film with higher uniformity. The basic process of exposure to gas A, no reactive gas, gas B, no reactive gas would be to sweep the substrate under the injectors to saturate the surface with chemical A and B respectively to avoid having a starting and ending pattern form in the film. The inventors have surprisingly found that the time based approach is especially beneficial when the target film thickness is thin (e.g., less than 20 ALD cycles), where starting and ending pattern have a significant impact on the within wafer uniformity performance. The inventors have also discovered that the reaction process to create SiCN, SiCO and SiCON films, as described herein, could not be accomplished with a time-domain process. The amount of time used to purge the processing chamber results in the stripping of material from the substrate surface. The stripping does not happen with the spatial ALD process described because the time under the gas curtain is short.

Accordingly, embodiments of the disclosure are directed to processing methods comprising a processing chamber 100 with a plurality of processing regions 250a-250h with each processing region separated from an adjacent region by a gas curtain 150. For example, the processing chamber shown in FIG. 5. The number of gas curtains and processing regions within the processing chamber can be any suitable number depending on the arrangement of gas flows. The embodiment shown in FIG. 5 has eight gas curtains 150 and eight processing regions 250a-250h. The number of gas curtains is generally equal to or greater than the number of processing regions. For example, if region 250a had no reactive gas flow, but merely served as a loading area, the processing chamber would have seven processing regions and eight gas curtains.

A plurality of substrates 60 are positioned on a substrate support, for example, the susceptor assembly 140 shown FIGS. 1 and 2. The plurality of substrates 60 are rotated around the processing regions for processing. Generally, the gas curtains 150 are engaged (gas flowing and vacuum on) throughout processing including periods when no reactive gas is flowing into the chamber.

A first reactive gas A is flowed into one or more of the processing regions 250 while an inert gas is flowed into any processing region 250 which does not have a first reactive gas A flowing into it. For example if the first reactive gas is flowing into processing regions 250b through processing region 250h, an inert gas would be flowing into processing region 250a. The inert gas can be flowed through the first reactive gas port 125 or the second reactive gas port 135.

The inert gas flow within the processing regions can be constant or varied. In some embodiments, the reactive gas is co-flowed with an inert gas. The inert gas will act as a carrier and diluent. Since the amount of reactive gas, relative to the carrier gas, is small, co-flowing may make balancing the gas pressures between the processing regions easier by decreasing the differences in pressure between adjacent regions.

Some embodiments of the disclosure are directed to injector modules. While the injector modules are described with respect to a spatial ALD processing chamber, those skilled in the art will understand that the modules are not limited to spatial ALD chambers and can be applicable to any injector situation where increasing gas flow uniformity is useful.

Some embodiments of the disclosure advantageously provide modular plasma sources, i.e. a source that can be easily inserted into and removed from the processing system. Such a source may have all or most of its hardware operating at the same pressure level as the atomic layer deposition process, typically 1-50 Torr. Some embodiments of the disclosure provide plasma sources with improved ion flux across the wafer surface. One or more embodiments advantageously provide blocker plates for plasma sources that are relatively easy to manufacture, using a small number of elongate slotted apertures rather than a large number of small holes. Some embodiments advantageously improve uniformity of the plasma density above the substrate surface using a tilted blocker plate having a variable distance to the substrate surface. One or more embodiments of the disclosure provide a plasma source with improved metal contamination by providing a dielectric sleeve to protect conductive materials from direct plasma exposure.

The RF hot electrode creates a plasma in an 8.5 mm gap (the gap can range from 3 mm to 25 mm) between the hot electrode and a grounded electrode. The upper portion of the electrode may be covered by a thick dielectric (e.g., ceramic), which in turn may be covered by a grounded surface. The RF hot electrode and grounded structure are made of a good conductor, such as aluminum. To accommodate thermal expansion, two pieces of dielectric (e.g. ceramic) are placed at the long ends of the RF hot electrode. For example, grounded Al pieces are placed adjacent to the dielectric, without a gap between. The grounded pieces can slide inside the structure, and may be held against the ceramic with springs. The springs compress the entire “sandwich” of grounded Al/dielectric against the RF hot electrode without any gaps, eliminating or minimizing chance of spurious plasma. This holds the parts together, eliminating gaps, yet still allows some sliding due to thermal expansion.

Exposure of the wafer to the active species generated in the plasma is commonly accomplished by allowing the plasma to flow through an array of holes. The dimensions of the holes determine the relative abundances of active species arriving at the wafer surface. Holes that “run hot”, e.g. holes that provide charged particle flux in excess of neighboring holes can lead to non-uniformity in processing, and can lead to process induced damage to the wafer.

The wafer surface can be any suitable distance from the front face of the blocker plate 350. In some embodiments, the distance between the front face of the blocker plate 350 and the wafer surface is in the range of about 2 mm to about 16 mm, or in the range of about 4 mm to about 15 mm, or in the range of about 6 mm to about 14 mm, or in the range of about 8 mm to about 13 mm, or in the range of about 10 mm to about 13 mm or about 12 mm.

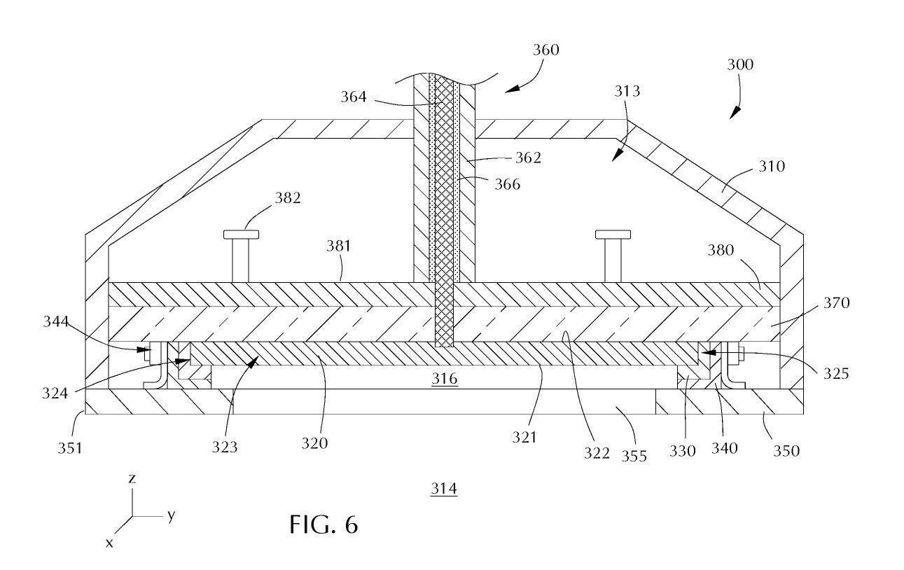

Referring to FIGS. 6 through 14, one or more embodiments of the disclosure are directed to modular capacitively coupled plasma sources 300. As used in this specification and the appended claims, the term “modular” means that plasma source 300 can be attached to or removed from a processing chamber. A modular source can generally be moved, removed or attached by a single person.

The plasma source 300 includes a housing 310 with a blocker plate 350 and a gas volume 313. The blocker plate 350 is electrically grounded and, in conjunction with the hot electrode 320 forms a plasma in gap 316. The blocker plate 350 has a thickness with an elongate slot 355 extending therethrough to allow plasma ignited in the gap 316 to pass through the elongate slot 355 into a processing region 314 on an opposite side of the blocker plate 350 from the gap 316. The thickness of the blocker plate 350 can be any suitable thickness; for example, in the range of about 0.5 mm to about 10 mm. The gap 316 can be any suitable size depending on, for example, the size or width of the hot electrode 320. In some embodiments, the gap 316 is in the range of about 3 mm to about 25 mm. In one or more embodiments, the gap 316 is in the range of about 4 mm to about 20 mm, or in the range of about 5 mm to about 15 mm, or in the range of about 6 mm to about 10 mm, or in the range of about 8 mm to about 9 mm, or about 8.5 mm.

The housing 310 can be round, square or elongate, which means that, when looking at the face of the blocker plate 350, there is a long axis and a short axis. For example, a rectangle having two long sides and two short sides would create an elongate shape with an elongate axis extending halfway between the long sides. In some embodiments, the housing 310 is wedge shaped having two long sides a short end and a long end. The short end can come to a point and either or both of the short end and long end can be straight or curved.

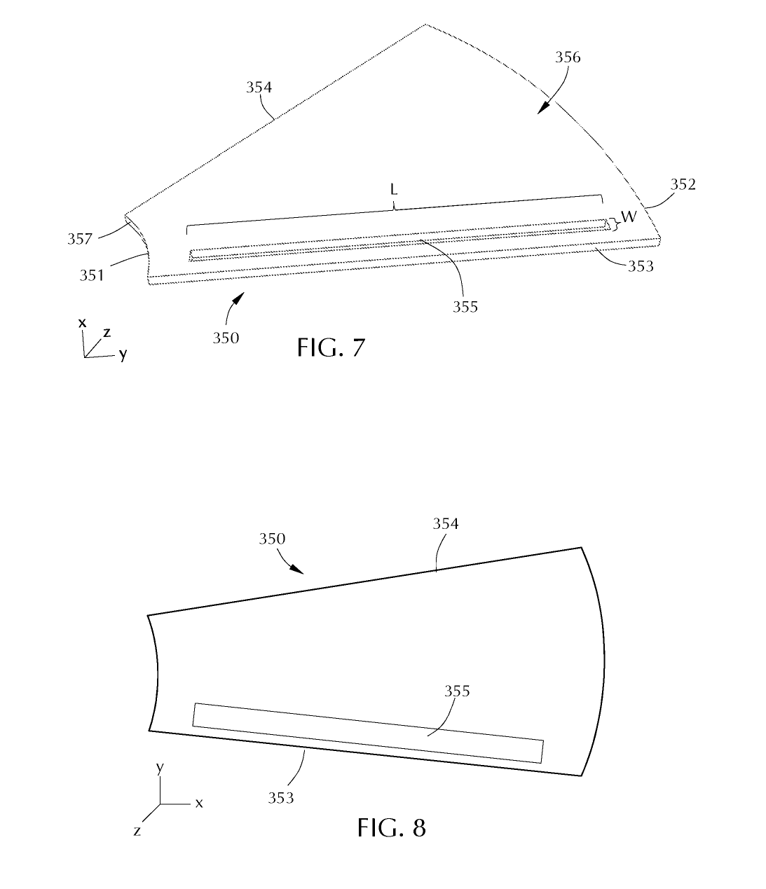

The blocker plate 350 is in electrical communication with the housing 310. The blocker plate 350 of some embodiments, as shown in the view of FIG. 7, has an inner peripheral edge 351, an outer peripheral edge 352, a first side 353 and a second side 354 defining a field 356. An elongate slot 355 is located within the field 356 and extends through the thickness 357 of the blocker plate 350. The elongate slot 355 has a length L and a width W. The slot can be linear, curved, wedge-shaped or oval shaped. As used in this regard, a linear slot has elongate edges that are spaced from each other by a distance that does not vary by more than 5% relative to the average distance between the edges. If the slot has curved ends, the distance between the edges of the slot is determined based on the middle 90% of the slot length.

The size and shape of the elongate slot 355 can vary with, for example, the size and shape of the blocker plate 350 and/or housing 310. The width and length of the slot may affect the uniformity of the plasma density. In some embodiments, the elongate slot 355 has a width W in the range of about 2 mm to about 20 mm, or in the range of about 3 mm to about 16 mm, or in the range of about 4 mm to about 12 mm. The inventors have surprisingly found that the plasma density adjacent the sides of an elongate slot are greater than the plasma density in the central portion of the slot. Decreasing the width of the slot can increase the plasma density. The inventors have also surprisingly found that the decrease in the slot width and increase in the plasma density is a non-linear relationship.

The length L of the elongate slot 355 of some embodiments is in the range of about 20% to about 95% of a distance between the inner peripheral edge 351 and outer peripheral edge 352 of the blocker plate 350. In some embodiments, the length L of the elongate slot 355 is greater than about 30%, 40%, 50%, 60%, 70% or 80% of the distance between the inner peripheral edge 351 and the outer peripheral edge 352 of the blocker plate 350.

The blocker plate 350 can be any suitable shape depending on, for example, the shape of the housing 310 and the path traveled by substrates relative to the blocker plate 350. In some embodiments, as shown in FIG. 8, the blocker plate 350 is wedge shaped with a narrower width at the inner peripheral edge 351 than at the outer peripheral edge 352. In some embodiments, as shown in FIG. 8, the elongate slot 355 is substantially parallel to one of the first side 353 or the second side 354 of the blocker plate 350, shown here parallel to the first side 353. As used in this specification and the appended claims, the term “substantially parallel” used in this regard means that the edge of the elongate slot 355 nearest the stated side remains a distance from the stated side that varies by no more than about 20%, 15%, 10% or 5% relative to the average distance between the slot and the side. Because the blocker plate 350 is wedge-shaped and the elongate slot 355 is rectangular, geometrically the slot cannot be parallel to more than one side.

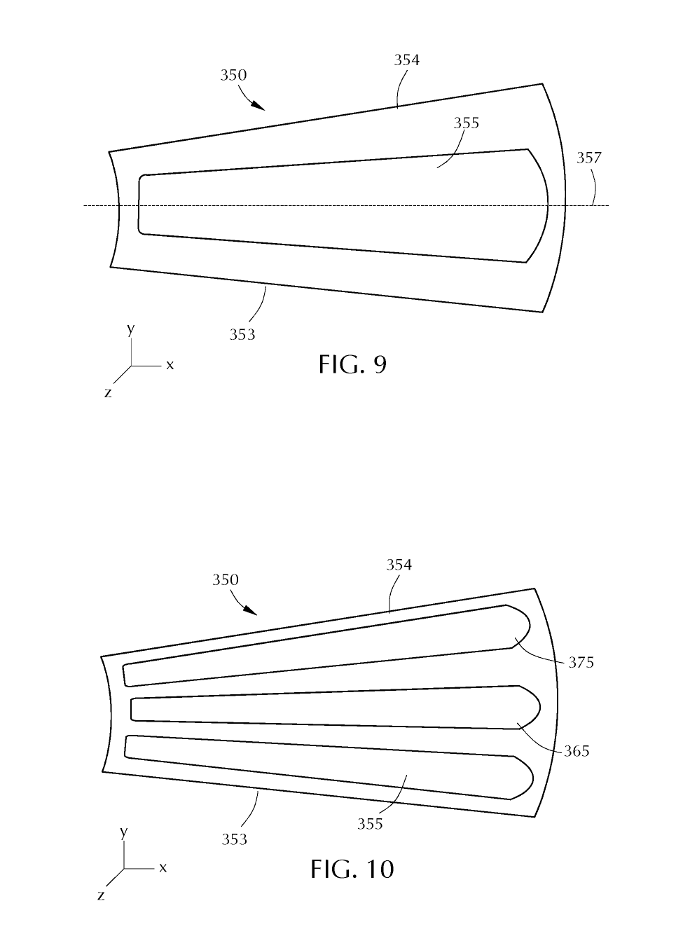

In some embodiments, the length L of the elongate slot 355 is substantially parallel to at least one of the first side 353 and/or second side 354 of the blocker plate 350. The embodiment of FIG. 9 shows a wedge shaped slot 355 centered along the central axis 357 of the field 356 of a wedge-shaped blocker plate 350. In this embodiment, both sides of the elongate slot 355 are substantially parallel to the first side 353 or the second side 354. The wedge shaped slot 355 of this embodiment has a narrower width near the inner peripheral edge 351 of the field 356 than near the outer peripheral edge 352 of the field 356.

In some embodiments, neither side of the elongate slot is parallel to either the first side or the second side of the blocker plate. For example, a rectangular blocker plate 350 that has a rectangular elongate slot may have both sides of the elongate slot substantially parallel to both the first side and the second side of the blocker plate. Similarly, if a rectangular slot is skewed from the center line of the width of the blocker plate, then the elongate slot would not be parallel to either side of the blocker plate.

The number of elongate slots 355 can be varied. In some embodiments, there is a first elongate slot 355 in the field 356 and a second elongate slot 365 in the field 356. In the embodiment shown in FIG. 10, the blocker plate 350 has a field 356 including a first elongate slot 355, a second elongate slot 365 and a third elongate slot 375. Each of the elongate slots 355, 365, 375 are wedge shaped but could be either wedge shaped or rectangular.

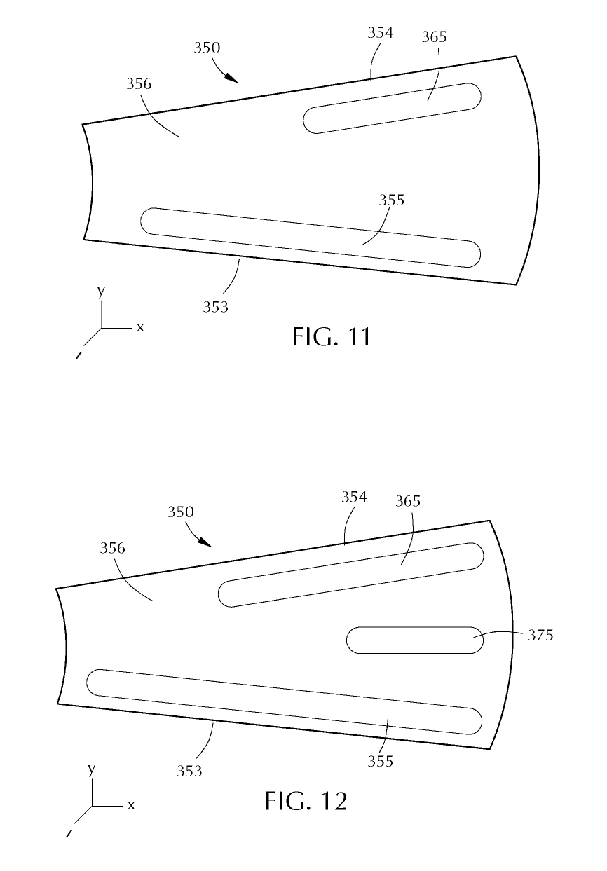

FIG. 11 shows another embodiment in which the field 356 has a first elongate slot 355 and a second elongate slot 365. Both of these elongate slots are rectangular and each is substantially parallel to a different side of the blocker plate. As used in this regard, “rectangular” means a generally rectangular shape and allows for the rounding of the ends so that there are no right angles. The first elongate slot 355 can be substantially parallel to one of the first side 353 or the second side 354 and the second elongate slot 365 can be substantially parallel to the other of the first side 353 and the second side 354 of the blocker plate 350. In the embodiment shown, the first elongate slot 255 is substantially parallel to the first side 353 and the second elongate slot 365 is substantially parallel to the second side 354.

When multiple elongate slots are included in a blocker plate 350, the lengths of each of the slots can be the same as or different from the length of other slots. The embodiment of FIG. 10 has three elongate slots of approximately equal length while FIG. 11 shows a first slot that is longer than the second slot. In some embodiments, the second elongate slot, if a different length from the first elongate slot, has a length in the range of about 20% to about 80% of the first elongate slot.

FIG. 12 shows another embodiment of a blocker plate 350 in which there are three elongate slots. Here, each of the first elongate slot 355, the second elongate slot 365 and the third elongate slot 375 have different lengths. In some embodiments, the first elongate slot 355 is substantially parallel to and adjacent the first side 353 of the blocker plate 350. The second elongate slot 365 is substantially parallel to and adjacent the second side 354 of the blocker plate 350. The length of the second elongate slot 365 is in the range of about 20% to about 80% of the length of the first elongate slot 355. A third elongate slot 375 is between the first elongate slot 355 and the second elongate slot 365 and has a length in the range of about 20% to about 80% of the length of the second elongate slot 365. The third elongate slot 375 is shown substantially parallel to the second side 354 but can be oriented differently.

A linear slot has been observed to provide a more uniform plasma density in the inner peripheral edge to outer peripheral edge direction while rotation of the substrate results in a short exposure near the outer edge. A wedge shaped slot has been found to increase the exposure time near the outer edge but may have more variation in plasma density along the length. Having multiple linear slots can be used to increase the plasma exposure near the outer edge but may have a marked increase in plasma density where the shorter slot starts. An advantage to the linear slots is that additional slots can be used to increase the plasma exposure if needed.

Mixing linear and wedge shaped slots may improve plasma density and uniformity. In some embodiments, a first slot is linear and a second slot is shorter with an inverted wedge shape. As used in this regard, an inverted wedge shape means that the inner end of the slot is wider than the outer end of the slot. Without be bound to theory, it is believed that the increase in plasma density at the start of the second slot will be smaller than if a linear slot was used because the edges of the inverted wedge shape would be further away from each other at this position.

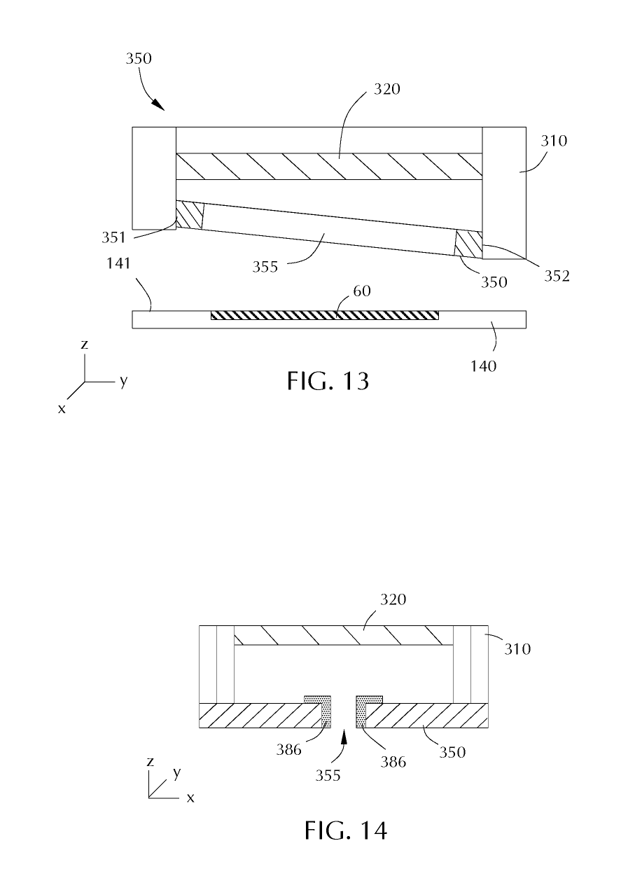

The blocker plate 350 can be substantially parallel to the top surface 141 of the susceptor assembly 140 or can be tilted. FIG. 13 shows an embodiment where the inner peripheral end 351 of the blocker plate 350 is higher than the outer peripheral end 352 of the blocker plate 350 relative to the top surface 141 of the susceptor assembly 140. When the blocker plate 350 is positioned adjacent a substrate 60, the inner peripheral end 351 is further from the substrate 60 than the outer peripheral end 352. Without being bound by theory, it is believed that tilting the blocker plate 350 with respect to the wafer surface changes the plasma density above the wafer as a function of distance to the surface. More ions near the outer edge can impact the wafer than near the inner edge and can be used to equalize exposure to the plasma from the inner edge to the outer edge.

Referring to FIG. 14, in some embodiments, the elongate slot 355 is lined with a dielectric material 386. Without being bound by theory, it is believed that lining the slot with a dielectric improves metal contamination by protecting the metal around the slot from being directly exposed to the plasma. This may help prevent or minimize sputtering of the metal blocker plate 350 from the edge of the slot 355 and reduce metal contamination. The dielectric material 386 is believed to decrease the plasma strength/density adjacent he front surface of the blocker plate. The dielectric material can be any suitable dielectric or low sputter material that is compatible with the process chemistry.

Referring back to FIG. 6, the plasma source 300 includes an RF hot electrode 320. This electrode 320 is also referred to as the “hot electrode”, “RF hot”, and the like. The elongate RF hot electrode 320 has a front face 321, a back face 322 and elongate sides 323. The hot electrode 320 also includes a first end 324 and second end 325 which define the elongate axis. The elongate RF hot electrode 320 is spaced from the blocker plate 350 so that a gap 316 is formed between the front face 321 of the hot electrode 320 and the blocker plate 350. The elongate RF hot electrode 320 can be made of any suitable conductive material including, but not limited to, aluminum.

Some embodiments include an end dielectric 330 in contact with one or more of the first end 324 and the second end 325 of the RF hot electrode 320. The end dielectric 330 is positioned between the RF hot electrode 320 and the side wall 311 of the plasma source 300 to electrically isolate the hot electrode 320 from electrical ground. In one or more embodiments, the end dielectric 330 is in contact with both the first end 324 and the second end 325 of the hot electrode 320. The end dielectric 330 can be made out of any suitable dielectric material including, but not limited to ceramic. The end dielectric 330 shown in the Figures is L-shaped, but any suitable shape can be used.

A sliding ground connection 340 may be positioned at one or more of the first end 324 and the second end 325 of the RF hot electrode 320 or the sides. The sliding ground connection 340 is positioned on an opposite side of the end dielectric 330 from the hot electrode 320. The sliding ground connection 340 is isolated from direct contact with the RF hot electrode 320 by the end dielectric 330. The sliding ground connection 340 and the end dielectric 330 cooperate to maintain a gas tight seal and allow the hot electrode 320 to expand without allowing leakage of gases around the side of the electrode. The sliding ground connection 340 is a conductive material and can be made of any suitable material including, but not limited to, aluminum. The sliding ground connection 340 provides a grounded termination to the side of the end dielectric 330 to ensure that there is no electric field, minimizing the chance of stray plasma to the side of the end dielectric 330.

A seal foil 342 may be positioned at the sliding ground connection 340 on an opposite side from the end dielectric 330. The seal foil 342 forms an electrical connection between the blocker plate 350 of the housing 310 and the sliding ground connection 340 as the sliding ground connection 340 slides on the blocker plate 350. The seal foil 342 can be made from any suitable conductive material including, but not limited to, aluminum. The seal foil 342 can be a thin flexible material that can move with the expansion and contraction of the hot electrode 320 so long as the electrical connection between the front face and the sliding ground connection is maintained.

A clamp face and nut 344 can be positioned at the end of the hot electrode 320, end dielectric 330, sliding ground connection 340 and seal foil 342 combination. Other clamp faces and nuts can be found at any side of the combination and multiple can be found along each side of the combination, depending on the size and shape of the plasma source. The clamp face and nut provide inwardly directed pressure to the combination of components to form a tight seal and prevent separation between the end dielectric 330 and the sliding ground connection 340 which might allow plasma gases to get behind the hot electrode 320. The clamp face and nut 344 can be made from any suitable material including, but not limited to, aluminum and stainless steel.

In some embodiments, a dielectric spacer 370 is positioned adjacent the back face 322 of the elongate RF hot electrode 320. The dielectric spacer 370 can be made of any suitable dielectric material including, but not limited to, ceramic materials. The dielectric spacer 370 provides a non-conductive separator between the RF hot electrode 320 and the top portion of the housing 310. Without this non-conductive separator, there is a chance that a plasma could be formed in the gas volume 313 due to capacitive coupling between the RF hot electrode 320 and the housing 310.

The dielectric spacer 370 can be any suitable thickness and made up of any number of individual layers. In the embodiment shown in FIG. 6, the dielectric spacer 370 is made up of one layer but multiple layers can be used which make up the total thickness of the dielectric spacer 370. Each of the individual sub-layers can be the same thickness or each can have an independently determined thickness.

Above the dielectric spacer 370, in some embodiments, is a grounded plate 380 positioned within the housing 310 and on an opposite side of the dielectric spacer 370 from the RF hot electrode 320. The grounded plate 380 is made of any suitable electrically conductive material including, but not limited to, aluminum, which can be connected to electrical ground. This grounded plate 380 further isolates the RF hot electrode 320 from the gas volume 313 to prevent plasma formation in the gas volume 313 or in a region other than the gap 316 where the plasma is intended to be formed.

Although the Figures show the grounded plate 380 to be about the same thickness as the dielectric spacer 370, or the sum of the individual dielectric spacer layers, this is merely one possible embodiment. The thickness of the grounded plate 380 can be any suitable thickness depending on the specific configuration of the plasma source. The thickness of the grounded plate in some embodiments is chosen based on, for example, thin enough to make drilling of gas holes easier, but thick enough to withstand the forces of the various springs mentioned. Additionally, the thickness of the grounded plate 380 may be tuned to ensure that the coaxial feed, which is typically a welded connection, can be adequately attached.

Some embodiments of the disclosure include a plurality of compression elements 382. The compression elements 382 direct force against a back surface 381 of the grounded plate 380 in the direction of the RF hot electrode 320. The compressive force causes the grounded plate 380, dielectric spacer 370 and RF hot electrode 320 to be pressed together to minimize or eliminate any spacing between each adjacent component. The compressive force helps prevent gases from flowing into the space being the RF hot electrode where they may become stray plasma. Suitable compression elements 382 are those which can be adjusted or tuned to provide a specific force to the back surface 381 of the grounded plate 380 and include, but are not limited to, springs and screws.

A coaxial RF feed line 360 passes through the elongate housing 310 and provides power for the RF hot electrode 320 to generate the plasma in the gap 316. The coaxial RF feed line 360 includes an outer conductor 362 and an inner conductor 364 separated by an insulator 366. The outer conductor 362 is in electrical communication with electrical ground and the inner conductor 364 is in electrical communication with the elongate RF hot electrode 320. As used in this specification and the appended claims, the term “electrical communication” means that the components are connected either directly or through an intermediate component so that there is little electrical resistance.

The coaxial RF feed may be constructed so that the outer conductor terminates on the grounded plate. The inner conductor can terminate on the RF hot electrode. If the feed is at atmospheric pressure, O-rings may be positioned at the bottom of the feed structure to enable medium pressure inside the source. In some embodiments, the gas is fed to the source around the outside periphery of the coaxial feed.

In order for gas to reach the plasma volume, the ground plate, thick ceramic, and RF hot electrode might be perforated with through holes. The size of the holes may be small enough to prevent ignition inside the holes. For the ground plate and RF hot electrode, the hole diameter of some embodiments is <1 mm, for example about 0.5 mm. The high electric fields inside the dielectric may help eliminate or minimize the chances of stray plasma in the holes.

The RF feed may be in the form of a coaxial transmission line. The outer conductor is connected to or terminated in the grounded plate, and the inner conductor is connected to or terminated in the RF hot electrode. The grounded plate can be connected to the metal enclosure or housing by any suitable method including, but not limited to, a metal gasket. This helps to ensure a symmetric geometry of the return currents. All return currents flow up the outer conductor of the feed, minimizing RF noise.

In some embodiments, the RF feed is designed to provide symmetric RF feed current to the hot plate, and symmetric return currents. All return currents flow up the outer conductor, minimizing RF noise, and minimizing impact of source installation on operation.

Additional embodiments of the disclosure are directed to methods comprising positioning a substrate in a processing chamber adjacent a blocker plate of a plasma source assembly. The blocker plate being any of the various embodiments described herein. A plasma is then generated in the plasma source and allowed to flow through the slot(s) in the blocker plate toward the substrate.

### Examples

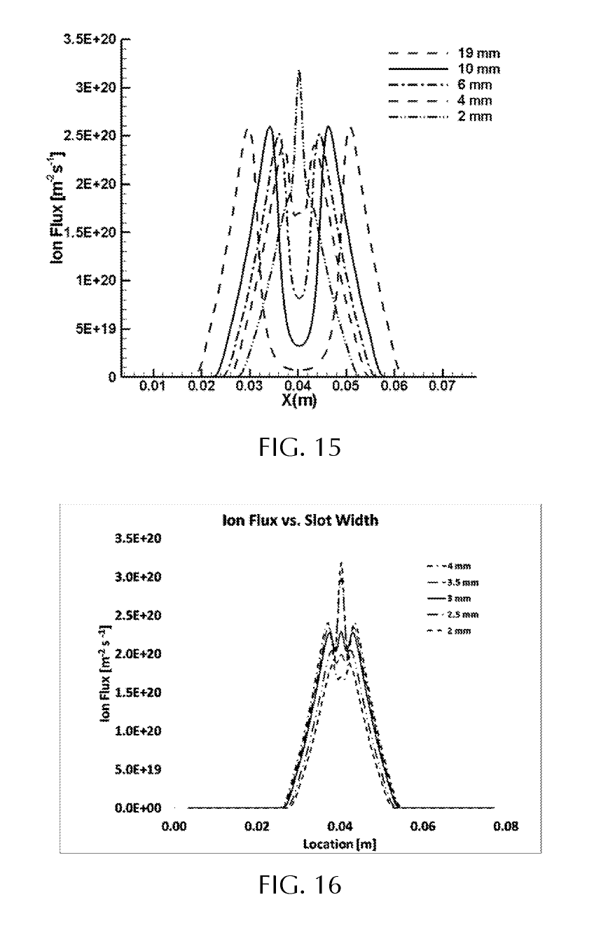

Plasma assemblies using blocker plates with various width slots were analyzed for ion flux uniformity. FIGS. 15 and 16 show graphs of the ion flux of a plasma as a function of the slot width. An argon plasma at 200 W, 13.5 MHz was used for these studies. Blocker plates with slot widths of 19 mm, 10 mm, 6 mm, 4 mm, 3.5 mm, 3 mm, 2.5 mm and 2 mm were analyzed. It was found that for wide slots, the plasma density peaks near the edges of the slot. At larger slot widths, as seen in FIG. 15, two peaks were observed in the ion flux. As the slot width decreased, the plasma density increased as the plasma peaks near the slot opening merged, as seen in the 2 mm slot in FIG. 15. Further studies, as shown in FIG. 16, indicated that the ion flux transitioned from two peaks to a single peak when the slot had a width of about 3 mm.

Some embodiments of the disclosure are directed to processing chambers comprising at least one capacitively coupled wedge-shaped plasma source 100 positioned along an arcuate path in a processing chamber. As used in this specification and the appended claims, the term “arcuate path” means any path which travels at least a portion of a circular-shaped or an oval-shaped path. The arcuate path can include the movement of the substrate along a portion of the path of at least about 5°, 10°, 15°, 20°,

Additional embodiments of the disclosure are directed to methods of processing a plurality of substrates. The plurality of substrates is loaded onto substrate support in a processing chamber. The substrate support is rotated to pass each of the plurality of substrates across a gas distribution assembly to deposit a film on the substrate. The substrate support is rotated to move the substrates to a plasma region adjacent a capacitively coupled pie-shaped plasma source generating substantially uniform plasma in the plasma region. This is repeated until a film of predetermined thickness is formed.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing between each layer deposition (e.g., exposure to plasma).

The frequency of the plasma may be tuned depending on the specific reactive species being used. Suitable frequencies include, but are not limited to, 400 kHz, 2 MHz, 13.56 MHz, 27 MHz, 40 MHz, 60 MHz and 100 MHz.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present disclosure, other and further embodiments of the disclosure may be devised without departing from the basic scope thereof, and the scope thereof is determined by the claims that follow.

What is claimed is:

1. A plasma source assembly comprising:
a housing;
a blocker plate in electrical communication with the housing, the blocker plate having an inner peripheral edge, an outer peripheral edge, a first side and a second side defining a field, an elongate slot is within the field and extends through the blocker plate, the elongate slot having a length and a width; and
an RF hot electrode within the housing, the RF hot electrode having a front face and a back face, an inner peripheral end and an outer peripheral end, the front face of the RF hot electrode spaced from the blocker plate to define a gap.

2. The plasma source assembly of claim 1, wherein the length of the elongate slot is substantially parallel to at least one of the first side and/or second side of the blocker plate.

3. The plasma source assembly of claim 1, wherein the elongate slot has a width in the range of about 2 mm to about 20 mm.

4. The plasma source assembly of claim 1, wherein the length of the elongate slot is in the range of about 50% to about 95% of a distance between the inner peripheral edge and outer peripheral edge.

5. The plasma source assembly of claim 1, wherein the blocker plate is wedge shaped with a narrower width at the inner peripheral edge than at the outer peripheral edge.

6. The plasma source assembly of claim 5, wherein the elongate slot is parallel to one of the first side or the second side of the blocker plate.

7. The plasma source assembly of claim 5, wherein the elongate slot is centered along a central axis of the field.

8. The plasma source assembly of claim 7, wherein the elongate slot is wedge shaped having a narrower width near the inner peripheral edge of the field than near the outer peripheral edge of the field.

9. The plasma source assembly of claim 5, wherein there is a first elongate slot in the field and a second elongate slot in the field.

10. The plasma source assembly of claim 9, wherein the first elongate slot is substantially parallel to one of the first side or second side of the blocker plate and the second elongate slot is substantially parallel to the other of the first side and the second side.

11. The plasma source assembly of claim 9, wherein the first elongate slot has a length different from the second elongate slot.

12. The plasma source assembly of claim 11, wherein the first elongate slot is substantially parallel to the first side of the blocker plate and the second elongate slot has a shorter length that the first elongate slot and is substantially parallel to the second side of the blocker plate.

13. The plasma source assembly of claim 5, wherein there is a first elongate slot in the field, a second elongate slot in the field and a third elongate slot in the field.

14. The plasma source assembly of claim 13, wherein each of the first elongate slot, the second elongate slot and the third elongate slot have different lengths.

15. The plasma source assembly of claim 14, wherein the first elongate slot is substantially parallel to and adjacent the first side of the blocker plate, the second elongate slot is substantially parallel to and adjacent the second side of the blocker plate and has a length in the range of about 50% to about 80% of a length of the first elongate slot, and the third elongate slot is between the first elongate slot and the second elongate slot and has a length in the range of about 50% to about 80% of the length of the second elongate slot.

16. The plasma source assembly of claim 5, wherein the inner peripheral end of the blocker plate is higher than the outer peripheral end of the blocker plate so that when positioned adjacent a substrate, the inner peripheral end is further from the substrate than the outer peripheral end.

17. The plasma source assembly of claim 5, wherein the elongate slot is lined with a dielectric material.

18. The plasma source assembly of claim 5, further comprising:
an end dielectric in contact with each of the inner peripheral end and the outer peripheral end of the RF hot electrode and between the RF hot electrode and a side wall of the housing;
a sliding ground connection positioned at one or more of the inner peripheral end and the outer peripheral end of the RF hot electrode opposite the end dielectric, the sliding ground connection isolated from direct contact with the RF hot electrode by the end dielectric;
a seal foil positioned at each sliding ground connection opposite the end dielectric, the seal foil forming an electrical connection between the front face of the elongate housing and the sliding ground connection;
a dielectric spacer within the housing and positioned adjacent the back face of the RF hot electrode;
a grounded plate within the housing and positioned on an opposite side of the dielectric spacer from the RF hot electrode, the grounded plate connected to electrical ground;
a coaxial RF feed line passing through the elongate housing, the coaxial RF feed line including an outer conductor and an inner conductor separated by an insulator, the outer conductor in communication with electrical ground and the inner conductor in electrical communication with the RF hot electrode; and
a plurality of compression elements to provide compressive force to the grounded plate in the direction of the dielectric spacer,
wherein the housing and each of the RF hot electrode, dielectric spacer and grounded plate are wedge-shaped with an inner peripheral edge, an outer peripheral edge and two elongate sides, the first end defining the inner peripheral edge and the second end defining the outer peripheral edge of the housing.

19. A plasma source assembly comprising:
a wedge-shaped housing having an inner peripheral end, an outer peripheral, a first side and a second side;
a wedge-shaped blocker plate in electrical communication with the housing, the blocker plate having an inner peripheral edge, an outer peripheral edge, a first side and a second side defining a field, the field comprises a first elongate slot substantially parallel to the first side of the blocker plate, a second elongate slot extending through the blocker plate substantially parallel to the second side of the blocker plate and a third elongate slot between the first elongate slot and the second elongate slot, the third elongate slot having a length in the range of about 20% to about 80% of a length of the second elongate slot and the second elongate slot has a length in the range of about 20% to about 80% of a length of the first elongate slot; and
a wedge-shaped RF hot electrode within the housing, the RF hot electrode having a front face and a back face, an inner peripheral end and an outer peripheral end, the front face of the RF hot electrode spaced from the blocker plate to define a gap.

20. A processing chamber comprising:
a susceptor assembly within the processing chamber, the susceptor assembly having a top surface to support and rotate a plurality of substrates around a central axis; and
a gas distribution assembly having a front surface facing the top surface of the susceptor assembly to direct a flow of gases toward the top surface of the susceptor assembly, the gas distribution assembly including a plasma source assembly comprising
a wedge-shaped housing having an inner peripheral end, an outer peripheral, a first side and a second side;
a wedge-shaped blocker plate in electrical communication with the housing, the blocker plate having an inner peripheral edge, an outer peripheral edge, a first side and a second side defining a field, the field comprises a first elongate slot substantially parallel to the first side of the blocker plate, a second elongate slot extending through the blocker plate substantially parallel to the second side of the blocker plate and a third elongate slot between the first elongate slot and the second elongate slot, the third elongate slot having a length in the range of about 20% to about 80% of a length of the second elongate slot and the second elongate slot has a length in the range of about 20% to about 80% of a length of the first elongate slot, and
a wedge-shaped RF hot electrode within the housing, the RF hot electrode having a front face and a back face, an inner peripheral end and an outer peripheral end, the front face of the RF hot electrode spaced from the blocker plate to define a gap,
wherein the inner peripheral end of the blocker plate is spaced further from the top surface of the susceptor assembly than the outer peripheral end of the blocker plate.
